(19) United States
(12) Patent Application Publication
(10) Pub. No.: US 2024/0219432 A1
(43) Pub. Date: Jul. 4, 2024

(54) ELECTRIC VOLTAGE MEASURING DEVICE USING AN MICROELECTROMECHANICAL SYSTEM WITH GRAPHENE

(71) Applicant: AIRBUS OPERATIONS, S.L.U., Getafe (ES)

(72) Inventors: David VICENTE OLIVEROS, Getafe (ES); Carlos ANDRES GONZALEZ, Getafe (ES); Salvador SALES MAICAS, Valencia (ES); Hector GARCIA MIGUEL, Valencia (ES)

(21) Appl. No.: 18/396,947

(22) Filed: Dec. 27, 2023

(30) Foreign Application Priority Data
Dec. 29, 2022 (ES) P202231115

(51) Int. Cl. G01R 15/24

(52) U.S. Cl. CPC G01R 15/248

(57) ABSTRACT

An electrical voltage measurement device, comprising at least one microelectromechanical device comprising a semitransparent material element with a variable refractive index n according to an electrical voltage applied to the element, a first electrode connectable to an anode of an electrical voltage source and electrically connected to a first point of the semitransparent material element, a second electrode connectable to a cathode of the electrical voltage source and electrically connected to a second point of the semitransparent material element, wherein the semitransparent material element is configured to receive an electrical voltage from the electrical voltage source through the first electrode and/or the second electrode, causing a variation Δn(V) in the refractive index n proportionally to the electrical voltage; and an optical device.

### CROSS-REFERENCES TO RELATED APPLICATIONS

This application claims the benefit of Spanish Patent Application Number P202231115 filed on Dec. 29, 2022, the entire disclosure of which is incorporated herein by way of reference.

### FIELD OF THE INVENTION

The present invention relates to devices for measuring electric voltage values using microelectromechanical devices and optical processors.

### BACKGROUND OF THE INVENTION

Microelectromechanical Systems (MEMS) are micrometric devices that can contain moving parts, as well as processing or sensing units. MEMS can be used for a wide variety of applications ranging from ink deposition in printers to inertial measurement (accelerometers and gyroscopes). Their micrometric scale allows for easy installation and implementation in combination with optical interferometry.

Optical interferometry is a technique based on the analysis of interference patterns of emitted and reflected light to determine quantities such as distance or roughness.

Graphene is a laminar material formed by carbon atoms and is obtained from graphite. Among its characteristics are hardness, flexibility, and thermal and electrical conductivity. Currently, it has numerous applications in technology, particularly in photonics. Since graphene is composed of a single-atom-thick layer of carbon atoms (monolayer thickness), it is a material with high optical transparency in the spectrum range corresponding to visible, near-infrared, and ultraviolet wavelengths. For example, monolayer graphene transmits around 97.7% in the visible range and, therefore, is highly transparent.

Unfortunately, conventional methods for measuring electrical voltage use active electronic components that require electrical power, and therefore, pose a fire hazard through the generation of sparks, overheating, and short circuits. Therefore, for measuring electrical voltage in fuel cells, being able to measure electrical voltage by micromechanical and optical methods exclusively would greatly increase safety.

Unfortunately, conventional techniques for measuring electrical voltage at multiple points often require a large number of electrical lines, since each sensor has to be part of an isolated circuit. When the number of measurement points increases, for example, to measure the individual output of each element in a battery comprising multiple elements, composed of multiple cells, the disorder of the electrical lines significantly increases, adding complexity to the wiring system and its installation, as well as its weight, cost, and maintenance.

Therefore, there is a demand for obtaining small-scale strain gauges that provide measurements with a high level of accuracy, that are safe, easily scalable, that have a low manufacturing cost, and that use non-electrical measurement methods.

The present invention meets this demand.

### SUMMARY OF THE INVENTION

The present invention relates to a device for measuring voltage values proportional to a variation Δn(V) in the refractive index n of a semitransparent material element, for example, a layer of graphene as part of a microelectromechanical device. The variation Δn(V) in the refractive index n of the semitransparent material element is detectable by optical interferometry. The device allows scalability and can comprise one or more electromechanical or microelectromechanical devices with graphene.

The electrical voltage values are obtained by analyzing interferometry patterns of optical signals affected by the variation Δn(V) in the refractive index n of the semitransparent material element, which changes according to the electrical voltage being measured. Through an optical device using optical interferometry, electrical voltage values, or a variation in electrical voltage, are determined.

Thus, in a first aspect, the invention pertains to a device for measuring electrical voltage values, comprising at least one microelectromechanical device that includes a semitransparent material element, for example, a layer of graphene, with a refractive index n, and a first electrode electrically connected to the graphene layer. The first electrode can be connected to an anode of an electrical voltage source. The device also includes a second electrode electrically connected to the graphene layer and connectable to a cathode of the electrical voltage source. Al₂O₃ films are established between each electrode and the graphene layer, maintaining electrical isolation between the two electrodes as Al₂O₃ has high resistivity, serving as an insulator.

In one example, the first electrode is coated by a first layer of electrical insulator, and the second electrode is coated by a second layer of electrical insulator. In a particularization, the first and second layers of electrical insulator comprise aluminum oxide.

The semitransparent material element is configured to receive electrical voltage from the voltage source, causing a variation Δn(V) in the refractive index n of the semitransparent material element proportional to the electrical voltage. The device also includes an optical device configured to transmit an optical signal through the semitransparent material element and detect, through the optical device, an amplitude or phase modulation of the modified optical signal due to the interaction with the semitransparent material element. Said amplitude or phase modulation is proportional to the variation Δn(V) in the refractive index n.

Through the optical device, interference patterns can be obtained based on the amplitude or phase modulation of the modified optical signal, and the optical device can calculate the value of the electrical voltage from the voltage source to be measured or a variation in electrical voltage. This value or variation in electrical voltage can be determined based on the interference patterns detected in the optical device.

In one example, the microelectromechanical device is a MEMS device configured to receive electrical voltage from the electrical voltage source, causing a variation n in the refractive index Δn(V) of a graphene layer proportional to the electrical voltage. The optical device consists of an optical fiber that transmits light from an optical source, receives it, and returns it to an optical sensor, for example, a photodetector. The optical device can detect amplitude and/or phase modulation of the modified optical signal, which is proportional to the variation n in the refractive index Δn(V) of the graphene layer. Through the optical device, interference patterns are obtained based on the amplitude and/or phase modulation of the optical signal, and the optical device calculates the value of the electrical voltage (or a variation in electrical voltage) from the voltage source to be measured. This electrical voltage is determined based on the interference patterns detected in the optical processor

In a first alternative, the device includes a reflective (or partially reflective) plate, for example, a metallic plate, and the semitransparent material element comprises a graphene layer. The optical device includes a terminal of an optical fiber that forms a partially reflective element and is configured to receive the optical signal modified by the graphene layer, a laser, and an optical sensor. The optical device is configured to project the laser's optical signal through the optical fiber toward the graphene layer. The optical signal undergoes double reflection: one reflection of the optical signal modified by the graphene layer on the metallic plate and another reflection at the fiber-air interface. The coexistence of these two optical signals, the one reflected at the fiber-air interface and the one reflected on the metallic plate, causes optical interference. This interference pattern depends on the refractive index of the graphene layer n, which in turn depends on the electrical voltage applied to the graphene layer. The variation Δn(V) in the refractive index n of the graphene layer generates changes in amplitude and phase of the reflection of the optical signal, producing interference patterns dependent on the refractive index n of the graphene layer.

The optical signal coming from the optical device, functioning as an interferometer, can be transmitted remotely from the electrical voltage measurement device via the optical fiber. Thus, the electrical processing of the interferometer's optical signals can also be carried out remotely, where there are no safety requirements present in the storage area of voltage sources, which could be, for example, hydrogen fuel cells (it is of interest that there are no electrically powered devices in the location of fuel cells that could cause explosions in the event of possible short circuits).

Advantageously, optical interferometry carried out by the optical device does not require electrical power at the measurement point, thereby minimizing the risk of fire through spark generation, overheating, and short circuits. This is crucial in applications involving highly flammable substances, such as hydrogen (hydrogen fuel cells), or in any other environment where there is a risk of explosion or fire.

In a second alternative, the optical device comprises an optical fiber, a laser, and an optical sensor. The optical fiber includes two branches: a first branch and a second branch, parallel to the first branch. In this embodiment, the semitransparent graphene plate is positioned between the first branch of the optical fiber, which is divided into two sections, and the second branch of the optical fiber is interrupted by the atmosphere (air). The optical device is configured to transmit the optical signal through both the first and second branches using the laser. In the first branch, the optical signal is affected by a phase and/or amplitude variation that is proportional to the variation Δn(V) in the refractive index n, of the graphene layer. With the two optical signals, one passing through the graphene layer and the other through the air, interference patterns are obtained. These interference patterns arise from the variation in phase and amplitude of the optical signal through the first branch and the phase of the optical signal through the second branch (reference phase).

In another example, the second branch is interrupted by a second semitransparent material element with geometry equivalent to the semitransparent material element (graphene). In another example, the second branch is continuous. The first and second branches can be under identical environmental conditions: humidity, temperature, and/or atmosphere type.

Interrupting the second branch, placing in the interrupted portion of the second branch a semitransparent material element identical to the semitransparent material element interposed in the first branch—without applying electrical voltage to the semitransparent material element interposed in the second branch—and/or ensuring that the first branch and the second branch are under the same environmental conditions allows for increased sensitivity of a device according to the invention.

In the second alternative, the optical device can analyze a modulation of phase and/or amplitude of the optical signal transmitted through an optical fiber compared to a reference phase, where the phase modulation of the optical signal is directly related to the variation in Δn(V) the refractive index n of the graphene layer.

Another aspect of the invention relates to a system comprising the device according to the first aspect of the invention and at least one electrical voltage source. The electrical voltage source can be a fuel cell or a battery.

### BRIEF DESCRIPTION OF THE DRAWINGS

To complement the description being made and to help a better understanding of the features of the device for measuring electrical voltage values according to the present invention, schematic representations are provided, which, with an illustrative and non-limiting nature, depict the following:

FIG. 1 shows a first example of a device for measuring electrical voltage values according to the present invention.

FIG. 2 shows a second example of a device for measuring electrical voltage values according to the present invention.

### DETAILED DESCRIPTION OF THE PREFERRED EMBODIMENTS

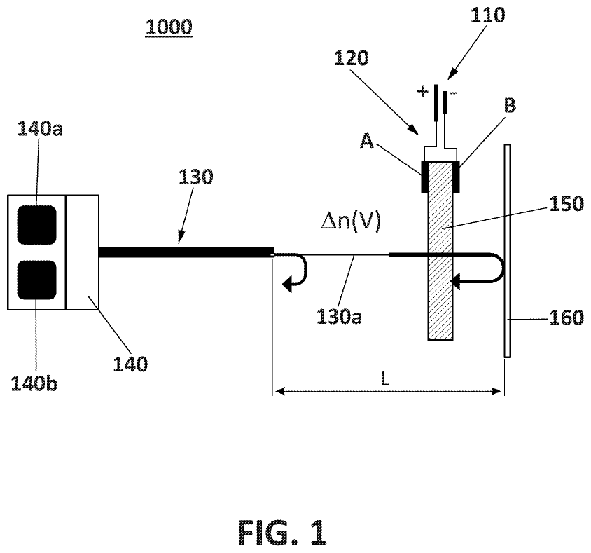

FIG. 1 shows a first example of a device (1000) for measuring electrical voltage values according to the present invention. The device (1000) comprises a microelectromechanical device (120) (for example, a MEMS) comprising a first electrode (A) connected to an anode (+) of an electrical voltage source (110), a second electrode (B) connected to a cathode (−) of said electrical voltage source (110), and a semitransparent material element (150), particularly, a graphene layer with a refractive index n. The graphene layer is electrically connected to the first electrode (A) and the second electrode (B). Between the first electrode (A), the second electrode (B), and the graphene layer, an insulating layer, for example, aluminum oxide, is interposed to prevent the flow of current between the first electrode (A) and the second electrode (B).

The microelectromechanical device (120) is configured to receive electrical voltage from the electrical voltage source (110), causing a variation Δn(V) in the refractive index n of the graphene layer proportional to the electrical voltage.

The voltage values are proportional to a variation in Δn(V) the refractive index n. This variation Δn(V) can be detectable and measured by an optical device (140) that functions as an interferometry system, creating an interferometric cavity (130a) using an optical fiber (130).

The optical device (140) may include different elements depending on the configuration of the device (1000) for measuring electrical voltage values. In this particular embodiment, the optical device (140) comprises the optical fiber (130), a laser (140a), and an optical sensor (140b).

The device (1000), moreover, includes a reflective plate (160), for example, a metallic plate established at a distance L from one end of the optical fiber (130), as can be seen in FIG. 1.

The optical device (140) is configured to project, through the laser (140a), the optical signal through the optical fiber (130) and towards the graphene layer, where the optical signal passes through the graphene layer obtaining a modified optical signal and undergoes reflection against the metallic plate.

The optical device (140) is configured to detect, through the optical fiber (130) and using the optical sensor (140b), the optical signal reflected at the fiber-air interface and the optical signal modified by the graphene layer and reflected on the metallic plate. The variation Δn(V) in the refractive index n of the graphene layer generates a variation in amplitude of the reflected modified optical signal.

The optical device (140) is configured to obtain interference patterns based on the optical signal reflected at the fiber-air interface and the optical signal modified by the graphene layer and reflected on the metallic plate.

Finally, the optical device (140) is configured to calculate the value (or a variation) of the electrical voltage (110) based on the interference patterns.

In addition, the device allows for the detection of a variation in electrical voltage.

Thus, the optical device (140), functioning as an interferometer, generates an interferometric cavity (130a) and detects through the sensor (140b) the optical signal and the reflection of the modified optical signal with the metallic plate, forming interference patterns. The interference patterns based on the optical signal and its reflection may vary depending on the modulation in amplitude of the reflected optical signal caused by the variation n in the refractive index Δn (V) of the graphene layer.

From the variation in interference patterns, the value of the electrical voltage applied to the electrodes (A, B) electrically connected to the graphene layer and provided by the electrical voltage source (110), which can be, for example, a fuel cell, can be derived. Therefore, modifications in the amplitude of the reflected signal, causing notable changes in interference patterns, can be detected through the optical device (140).

As shown in FIG. 1, the anode (+) and cathode (−) terminals of the electrical voltage source (110) are connected to the first electrode (A) and a second electrode (B) in the microelectromechanical device (120), respectively. When the electrical voltage source (110) applies a voltage to the microelectromechanical device (120), electrostatic forces generated by this voltage act on the graphene layer, causing a variation Δn(V) in the refractive index n of the graphene layer that is proportional to the potential difference or voltage applied by the electrical voltage source (110) to the microelectromechanical device (120). An insulating layer of aluminum oxide is established between the electrodes (A) and (B) and the graphene layer to prevent conduction between the electrodes of the microelectromechanical device (120).

As shown in FIG. 1, the optical fiber (130) is aligned to project a light beam representing the optical signal through the graphene layer. The optical signal is modified when passing through the graphene layer and collides with the metallic plate, causing a reflection of the optical signal that enters the optical fiber (130) through the optical fiber terminal. The optical fiber terminal forms a (partially) reflective element in such a way that it reflects a part of the optical signal emitted by the laser (140a) and transmits it back to the optical sensor (140b), forming a reference signal to generate optical interference by comparing this reference signal with the modified optical signal.

FIG. 1 also shows the interferometric cavity (130a). The optical signal, the reflected optical signal, and the reflection at the end of the fiber (fiber-air interface) constitute the interferometric cavity (130a), and its response is guided through the optical fiber (130) to the optical device (140), as shown in FIG. 1. In particular, the response of the interferometric cavity (130a) is read in the optical device (140), as interference patterns vary based on the modulation in amplitude of the reflected optical signal due to the variation Δn(V) in the refractive index n.

The optical device (140), functioning as a laser interrogator or interferometer, can accurately measure the modulation in amplitude of the reflected optical signal, such that:

$$F S R = c / ( 2 * n * L ) = c / [ 2 * ( nair * Lair + n * Lgraphene ) ] .$$

$$F S {R}^{′} = c / ( 2 * n * L ) = c / [ 2 * ( nair * Lair + ( n + Δ n ( V ) ) * Lgraphene ) ]$$

$$Δ F S R ( V ) = F S R - F S {R}^{′}$$

wherein FSR is the free spectral range observed in the interference pattern obtained by the optical device (140) taking into account the refractive index (n) of the graphene layer, and
where FSR′ is the free spectral range observed in the interference pattern obtained by the optical device (140) considering the refractive index (n) of the graphene layer with a variation in the refractive index Δn(V), and
where nair is the refractive index of air, and c is the speed of light.

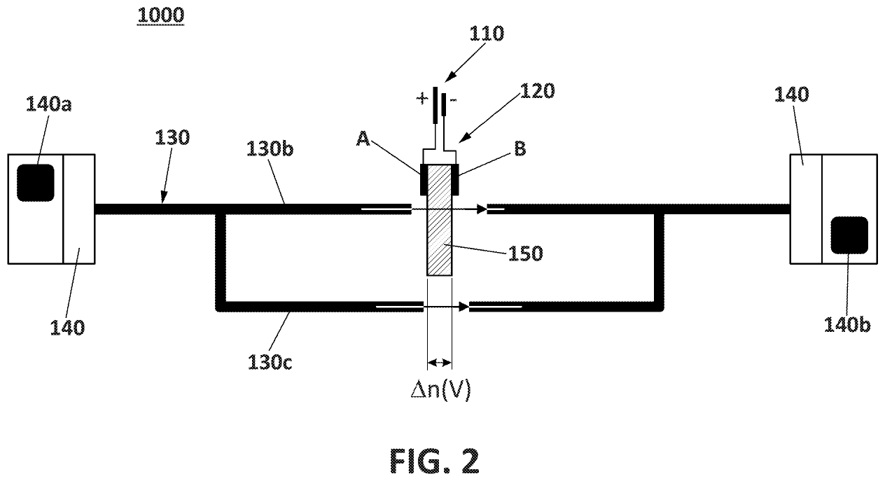

FIG. 2 shows another embodiment of the device (1000) for measuring electrical values according to the present invention. In this embodiment, the device (1000) functions as a Mach-Zehnder Modulator (MZM). The Mach-Zehnder Modulator (MZM) is an interferometric structure made of a material with strong electro-optical effects (such as LiNbO₃, GaAs, InP).

The microelectromechanical device (120) of the device (1000) is configured to receive an electrical voltage from the electrical voltage source (110), causing a variation Δn(V) in the refractive index n of the semitransparent material element (150) (e.g., a graphene layer) proportional to said electrical voltage, which is electrically connected to the first electrode (A) and the second electrode (B). Between the electrodes (A) and (B) and the graphene layer is a thin layer of aluminum oxide, insulating, to prevent conduction between the electrodes of the MEMS.

The optical device (140) comprises a laser (140a) configured to transmit an optical signal, with a specific phase, through the optical fiber (130). The optical fiber (130) comprises a first branch (130b) and a second branch (130c) parallel to the first branch (130b). Thus, the light signal is split through the first branch (130b) and the second branch (130c).

The optical device (140) comprises an optical sensor (140b) configured to detect the optical signals at the opposite end of the first branch (130b) and the second branch (130c). As shown in FIG. 2, the semitransparent material element (150) is interposed between a first part of the first branch (130b) and a second part of the first branch (130b), intersecting the path of the optical signal through the first branch (130b).

The optical device (140) is configured to detect, through the optical sensor (140b), a variation in the phase of the modified optical signal through the first branch (130b). Said phase variation is proportional to the variation in the Δn(V) refractive index n. When voltage is applied to the graphene layer, the phase of the optical signal passing through the graphene layer in the first branch (130b) varies with respect to the reference phase of the optical signal through the second branch (130c), as the reference phase is not disturbed by the graphene layer.

The optical device (140) is configured to obtain interference patterns based on the phase variation of the modified optical signal through the first branch (130b) compared to the reference phase of the optical signal through the second branch (130c).

In an example, the first branch (130b) and the second branch (130c) experience identical environmental conditions. Environmental conditions may include one or more of the following conditions: humidity, temperature, and/or type of atmosphere.

The application of an electric field by the electrical voltage source (110) alters the refractive index n of the graphene layer, changing the lengths of the optical paths, resulting in a phase modulation of the light signal passing through the graphene layer via the first branch (130b). Therefore, when a voltage is applied to the graphene layer, the phase of the light passing through it varies with respect to the reference phase of the undisturbed signal passing through the other line. The combination of the optical signals and the variation in their phases can be related to intensity modulation. This interference pattern can be measured in the other line and correlated with the voltage, such that:

$$F S R = c / ( n * L ) = c / [ nair * Lair + n * Lgraphene ]$$

$$F S {R}^{′} = c / ( n * L ) = c / [ ( nair * Lair + ( n + Δ n ( V ) ) * Lgraphene ) ]$$

$$Δ F S R ( V ) = F S R - F S {R}^{′}$$

wherein FSR is the observed free spectral range in the interference pattern obtained by the optical device (140) considering the refractive index n of the graphene layer, and FSR′ is the observed free spectral range in the interference pattern obtained by the optical device (140) considering the refractive index n of the graphene layer with a variation in the refractive index Δn(V), and
wherein nair is the refractive index of air, and c is the speed of light.

The systems and devices described herein may include a controller or a computing device comprising a processing and a memory which has stored therein computer-executable instructions for implementing the processes described herein. The processing unit may comprise any suitable devices configured to cause a series of steps to be performed so as to implement the method such that instructions, when executed by the computing device or other programmable apparatus, may cause the functions/acts/steps specified in the methods described herein to be executed. The processing unit may comprise, for example, any type of general-purpose microprocessor or microcontroller, a digital signal processing (DSP) processor, a central processing unit (CPU), an integrated circuit, a field programmable gate array (FPGA), a reconfigurable processor, other suitably programmed or programmable logic circuits, or any combination thereof.

The memory may be any suitable known or other machine-readable storage medium. The memory may comprise non-transitory computer readable storage medium such as, for example, but not limited to, an electronic, magnetic, optical, electromagnetic, infrared, or semiconductor system, apparatus, or device, or any suitable combination of the foregoing. The memory may include a suitable combination of any type of computer memory that is located either internally or externally to the device such as, for example, random-access memory (RAM), read-only memory (ROM), compact disc read-only memory (CDROM), electro-optical memory, magneto-optical memory, erasable programmable read-only memory (EPROM), and electrically-erasable programmable read-only memory (EEPROM), Ferroelectric RAM (FRAM) or the like. The memory may comprise any storage means (e.g., devices) suitable for retrievably storing the computer-executable instructions executable by processing unit.

The methods and systems described herein may be implemented in a high-level procedural or object-oriented programming or scripting language, or a combination thereof, to communicate with or assist in the operation of the controller or computing device. Alternatively, the methods and systems described herein may be implemented in assembly or machine language. The language may be a compiled or interpreted language. Program code for implementing the methods and systems described herein may be stored on the storage media or the device, for example a ROM, a magnetic disk, an optical disc, a flash drive, or any other suitable storage media or device. The program code may be readable by a general or special-purpose programmable computer for configuring and operating the computer when the storage media or device is read by the computer to perform the procedures described herein.

Computer-executable instructions may be in many forms, including modules, executed by one or more computers or other devices. Generally, modules include routines, programs, objects, components, data structures, etc., that perform particular tasks or implement particular abstract data types. Typically, the functionality of the modules may be combined or distributed as desired in various embodiments.

It will be appreciated that the systems and devices and components thereof may utilize communication through any of various network protocols such as TCP/IP, Ethernet, FTP, HTTP and the like, and/or through various wireless communication technologies such as GSM, CDMA, Wi-Fi, and WiMAX, is and the various computing devices described herein may be configured to communicate using any of these network protocols or technologies.

While at least one exemplary embodiment of the present invention(s) is disclosed herein, it should be understood that modifications, substitutions and alternatives may be apparent to one of ordinary skill in the art and can be made without departing from the scope of this disclosure. This disclosure is intended to cover any adaptations or variations of the exemplary embodiment(s). In addition, in this disclosure, the terms “comprise” or “comprising” do not exclude other elements or steps, the terms “a” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

Claimed is:

1. An electrical voltage measurement device, comprising:
at least one microelectromechanical device comprising:
a semitransparent material element with a variable n refractive index according to an electrical voltage applied to said element;
a first electrode configured to be connected to an anode of an electrical voltage source and electrically connected to a first point of the semitransparent material element;
a second electrode configured to be connected to a cathode of said electrical voltage source and electrically connected to a second point of the semitransparent material element,
wherein the semitransparent material element is configured to receive an electrical voltage from the electrical voltage source through the first electrode and/or the second electrode, causing a variation Δn(V) in a refractive index n proportional to said electrical voltage; and
an optical device configured to:
transmit an optical signal through the semitransparent material element;
capture at least one optical signal modified by an interaction of the optical signal with the semitransparent material element;
detect an amplitude or phase modulation of the modified optical signal that is proportional to the variation Δn(V) in the refractive index n;
obtain interference patterns based on at least said amplitude or phase modulation of the optical signal; and
calculate a value of the electrical voltage of the electrical voltage source based on the interference patterns.

2. The electrical voltage measurement device according to claim 1, further comprising:
a reflective plate, a laser, and an optical sensor, wherein the optical device is configured to:
project through the laser the optical signal towards the semitransparent material element causing a modification of the optical signal;
capture a reflection of a modified optical signal on the reflective plate;
detect, through the optical sensor, the variation Δn(V) in the refractive index n, wherein the variation Δn(V) generates a variation in amplitude of the reflection of the modified optical signal;
obtain interference patterns based on the variation in amplitude of the reflection of the modified optical signal.

3. The electrical voltage measurement device according to claim 2, wherein the optical device comprises an optical fiber configured to transmit the optical signal from the laser, and
wherein a terminal of the optical fiber forms a partially reflective element.

4. The electrical voltage measurement device according to claim 2, wherein the reflective plate is a metallic plate.

5. The electrical voltage measurement device according to claim 1, wherein the optical device comprises a laser, an optical sensor, and an optical fiber comprising a first branch and a second branch parallel to the first branch,
wherein the semitransparent material element is interposed between a first part of the first branch and a second part of the first branch,
wherein the optical device is configured to:
transmit, through the laser, the optical signal through the first branch and the semitransparent material element;
transmit, through the laser, the optical signal through the second branch;
detect, through the optical sensor, a modified optical signal through the first branch, wherein the phase and/or amplitude variation of the modified optical signal is proportional to the variation Δn(V) in the refractive index n of the semitransparent material element;
detect, through the optical sensor, a reference optical signal through the second branch;
obtain interference patterns based on the phase, amplitude variation, or both of the modified optical signal with respect to the reference optical signal.

6. The electrical voltage measurement device according to claim 5, wherein the second branch is interrupted by:
an atmosphere; or
a second element of semitransparent material with a geometry equivalent to the semitransparent material element interposed between the first part of the first branch and the second part of the first branch; or
both.

7. The electrical voltage measurement device according to claim 5, wherein the second branch is continuous.

8. The electrical voltage measurement device according to claim 5, wherein the first branch and the second branch are under identical environmental conditions.

9. The electrical voltage measurement device according to claim 8, wherein the identical environmental conditions comprise one or more of:
hygrometry,
temperature,
type of atmosphere, or
any combination thereof.

10. The electrical voltage measurement device according to claim 1, wherein the microelectromechanical device is a MEMS.

11. The electrical voltage measurement device according to claim 1, wherein the semitransparent material element comprises a graphene layer.

12. The electrical voltage measurement device according to claim 1, wherein the first electrode is coated by a first layer of electrical insulator and the second electrode is coated by a second layer of electrical insulator.

13. The electrical voltage measurement device according to claim 12, wherein the first layer of electrical insulator and the second layer of electrical insulator comprise aluminum oxide.

14. A system comprising:
the electrical voltage measurement device according to claim 1; and
at least one electrical voltage source.

15. The system according to claim 14, wherein the electrical voltage source is a fuel cell or a battery.
